(19) United States
(12) Patent Application Publication
(10) Pub. No.: US 2007/0145437 A1
(43) Pub. Date: Jun. 28, 2007

(54) IMAGE SENSOR AND METHOD OF MANUFACTURING THE SAME

(76) Inventor: Sang Sik Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/616,786

(22) Filed: Dec. 27, 2006

(30) Foreign Application Priority Data
Dec. 28, 2005 (KR) 10-2005-0131371

(51) Int. Cl. H01L 31/113

(52) U.S. Cl. 257/290

(57) ABSTRACT

An image sensor may include at least one of: a semiconductor substrate including a plurality of photodiodes and a pad section; a protective layer formed over a semiconductor substrate including a trench pattern; an interlayer dielectric layer formed over a cell area of a protective layer; a color filter layer formed over an interlayer dielectric layer to allow light having a specific wavelength band to pass through; a planar layer formed over a color filter layer; and/or a micro-lens formed over a planar layer to guide light into photodiodes.

The present application claims priority under 35 U.S.C. 119 and 35 U.S.C. 365 to Korean Patent Application No. 10-2005-0131371 (filed on Dec. 28, 2005), which is hereby incorporated by reference in its entirety.

### BACKGROUND

Image sensors may be semiconductor devices that convert optical images into electric signals. An image sensor may be a charge coupled device (CCD) image sensor or a complementary metal oxide semiconductor (CMOS) image sensor. Image sensors may include photodiodes for detecting light and logic circuits for converting detected light into electrical data signals. Photo sensitivity of an image sensor improves as more light is received by an image sensor.

Photo sensitivity of an image sensor may be improved by increasing a fill factor. A fill factor is a ratio of an area covered by photodiodes area of the entire area of an image sensor. Increasing a fill factor may be accomplished by a photo-gathering technology that may change the path of light incident onto areas not covered by photodiodes to redirect that light onto photodiodes.

An example of photo-gathering technology are micro-lens. Micro-lens may be convex micro-lens formed over a top surface of photodiodes using a material having relatively high light transmittance. Micro-lens may refract incident light to maximize the amount of light transmitted into photo-diodes. Light parallel to an optical axis of a micro-lens may be refracted by the micro-lens to focus light to a predetermined position on the optical axis.

An image sensor may include a photodiode, an interlayer dielectric layer, a color filter, a micro-lens, a pad section, and/or other components. A photodiode may detect light and covert the light into electric signals. An interlayer dielectric layer may insulate metal interconnections from each other. Color filter may filter different colors (e.g. the three primary colors red (R), green (G), and blue (B)). Micro-lens may guide light onto photodiodes.

A pad section may serve as a link between an image sensor and an external circuit. When optical images are converted into electric signals, the electrical signals may be transmitted to an external circuit.

FIG. 1 illustrates an example image sensor. As illustrated in FIG. 1, protective layer 22 may be formed over semiconductor substrate 10. Substrate 10 may include a plurality of photodiodes 40 and pad section 45. Protective layer 22 may not be formed over pad section 45, since pad section 45 may connect to an external circuit.

Interlayer dielectric layer 20 may be formed over protective layer 22. RGB color filter layers 30 may be formed over interlayer dielectric layer 20, which may correspondence with photodiodes 40. Planar layer 25 may be formed over color filter layers 30, which may planarize irregular surfaces of color filter layers 30. Micro-lenses 50 may be formed over planar layer 25, which may correspond with photodiodes 40 and color filter layers 30.

In some applications, it may be desirable to minimize (e.g. micro-size) image sensors, while maximizing the number of pixels in an image sensor. In some application, the number of pixels in a unit area of an image sensor may be maximized. When the size of a unit pixel is minimized, the size of an area covered by photodiodes may be reduced, which may lower the photo sensitivity of an image sensor. If an image sensor has relatively low photo sensitivity, it may not be possible to photograph an image in a dark place and/or color reproduction characteristics may be relatively low.

### SUMMARY

Embodiments relate to an image sensor, which may redirect light leakage into adjacent pixels by using total reflection. Embodiments relate to an image sensor which may photograph an image in a dark place with relatively high color reproduction. In embodiments, a trench pattern may be formed in a protective layer to prevent light leakage into an adjacent pixel. Embodiments relate to a method of manufacturing an image sensor with a trench pattern formed in a protective layer.

In embodiments, an image sensor comprises at least one of: a semiconductor substrate including a plurality of photodiodes and a pad section; a protective layer formed over a semiconductor substrate including a trench pattern; an interlayer dielectric layer formed over a cell area of a protective layer; a color filter layer formed over an interlayer dielectric layer to allow light having a specific wavelength band to pass through; a planar layer formed over a color filter layer; and/or a micro-lens formed over a planar layer to guide light into photodiodes.

In embodiments, a protective layer may include a material having a refractive index higher than a protective layer. A protective layer may include silicon oxide (SiO) based materials, in accordance with embodiments.

An interlayer dielectric layer may include silicon nitride (SiN) based materials, in accordance with embodiments. A silicon nitride based material may have a refractive index higher than a silicon oxide based material. In embodiments, light incident from the exterior may be totally reflected from an interfacial surface of a trench, when the incident angle of light exceeds a predetermined reference angle, which may effectively guide reflected light into a photodiode.

In embodiments, since light may guided into a photodiode through total reflection without being refracted into an adjacent pixel, photo sensitivity of an image sensor may be maximized. A trench in a protective layer may include a hole having a circular shape or a polygonal shape. A trench in a protective layer may have a size in a range of about 10 nm to about 3 μn, in embodiments.

Embodiments relate to a method of manufacturing an image sensor. A method in accordance with embodiments may include at least one of: forming a plurality of photodiodes and a pad section in a semiconductor substrate; forming a protective layer including a trench having a predetermined pattern over a semiconductor substrate; forming an interlayer dielectric layer over a protective layer; removing a predetermined portion of a interlayer dielectric layer formed over a pad section; forming a color filter layer over an interlayer dielectric layer; forming a planar layer over a color filter layer; and/or forming a micro-lens over a planar layer.

### BRIEF DESCRIPTION OF DRAWINGS

FIG. 1 is a schematic sectional view illustrating an image sensor.

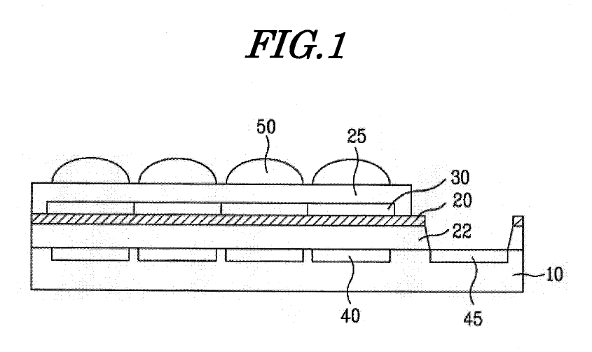

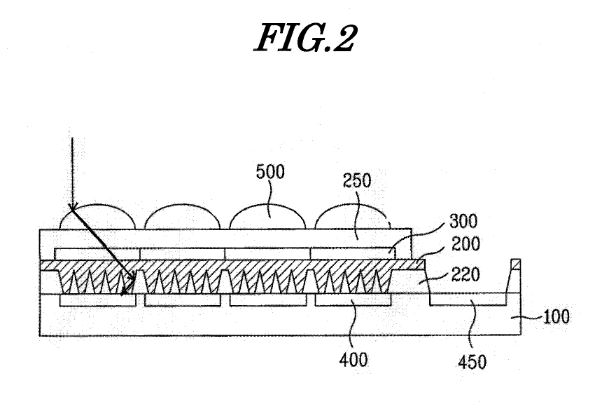

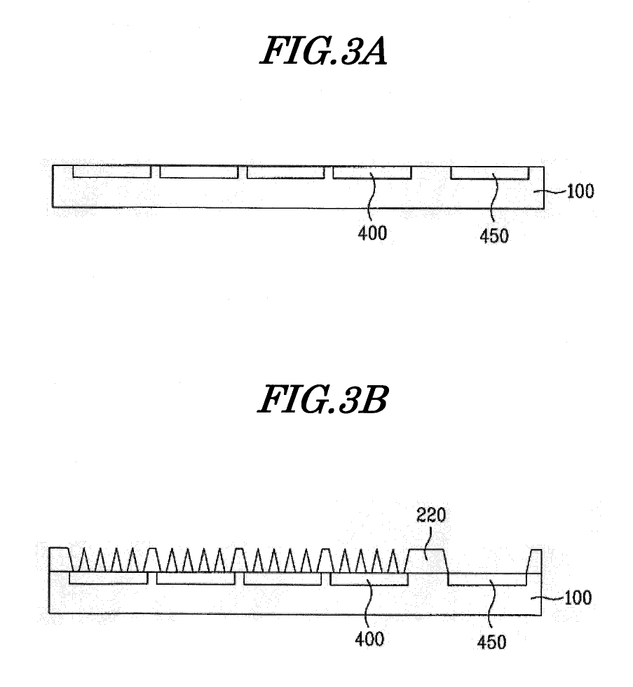

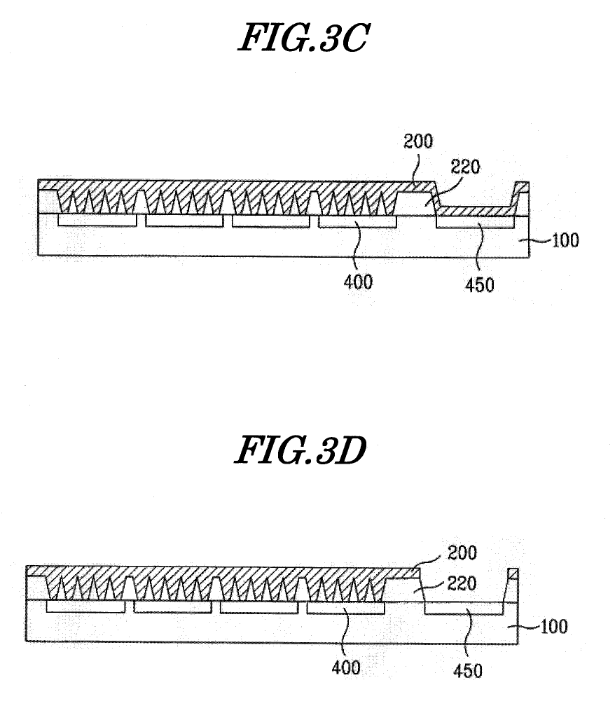

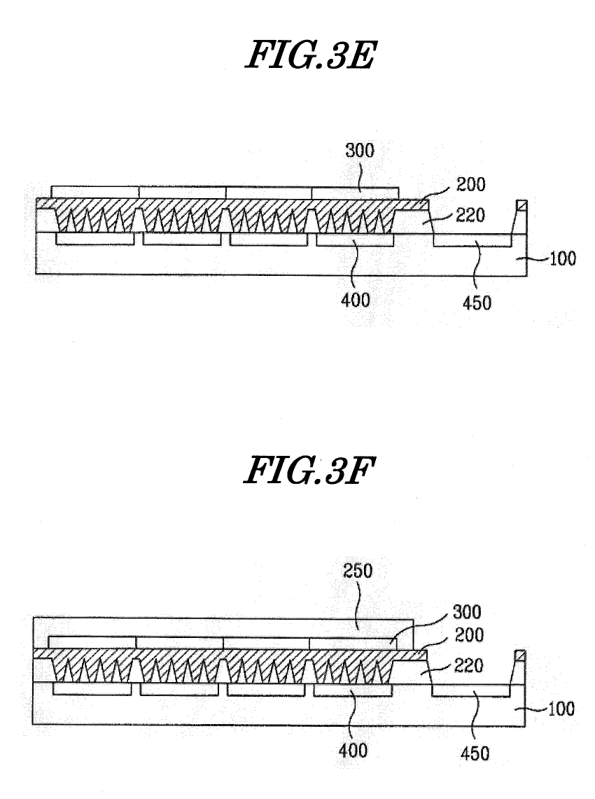

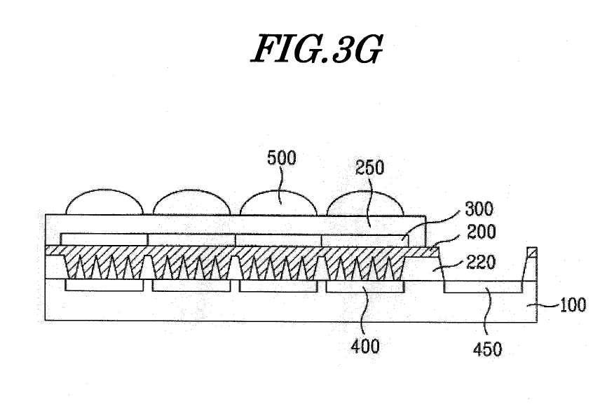

Example FIG. 2 is a schematic sectional view illustrating an image sensor, according to embodiments.

Example FIGS. 3A to 3G are sectional views illustrating a method of manufacturing an image sensor, according to embodiments.

### DETAILED DESCRIPTION

Example FIG. 2 is a schematic sectional view illustrating an image sensor, according to embodiments. As illustrated in FIG. 2, semiconductor substrate 100 may include a plurality of photodiodes 400 and pad section 450. Protective layer 220 may be formed over semiconductor substrate 100. Protective layer 220 may include silicon oxide (SiO) based materials, in accordance with embodiments.

A trench having a predetermined pattern may be formed in protective layer 220. In embodiments, the pitch of a trench in protective layer 220 may have a width of about 10 nm to about 3 μm. In embodiments, the depth of a trench in protective layer 220 may be the thickness of protective layer 220 or less than the thickness of protective layer 220.

Interlayer dielectric layer 200 may be formed over protective layer 220. In embodiments, interlayer dielectric layer 200 may include silicon nitride (SiN) based materials. Interlayer dielectric layer 200 may fill a trench formed in protective layer 220. In embodiments, a silicon nitride (SiN) based material (e.g. a material included in interlayer dielectric layer 200) may have a refractive index higher than a silicon oxide (SiO) based material (e.g. a material included in protective layer 220). In embodiments, the refractive index of interlayer dielectric layer 200 is greater than the refractive index of protective layer 220. In accordance with embodiments, light incident on protective layer 220 may be reflected into photodiode 400 from interfacial surfaces of trenches in protective layer 220.

In embodiments, at least one of interlayer dielectric layer 200 and/or protective layer 220 may include transparent insulating materials. The materials for interlayer dielectric layer 200 and/or protective layer 220 may not be limited to silicon nitride (SiN) and silicon oxide (SiO). In embodiments, the material included in interlayer dielectric layer 200 and protective layer 220 allow the refractive index of dielectric layer 200 to be higher than protective layer 220.

If trenches are not formed in protective layer 220, light incident on protective layer 220 may be refracted from one pixel to an adjacent pixel. In embodiments, trenches formed in protective layer 220 may prevent light from being refracted into an adjacent pixel. In embodiments, dielectric layer 200 (which may fill trenches) having a refractive index higher than protective layer 220 may prevent light fro being refracted into an adjacent pixel. In embodiments, light may be prevented from being refracted to adjacent pixels through internal reflection on sidewalls of trenches above a pixel.

In embodiments, protective layer 220 may engage with interlayer dielectric layer 200 through trenches. In embodiments, peeling of interlayer dielectric layer 200 may be prevented or minimized. In embodiments, adhesion between protective layer 220 and dielectric layer 200 may be maximized.

Protective layer 220 and interlayer dielectric layer 200 may not be formed over pad section 450. Since pad section 450 may serve as a link between an image sensor and an external circuit, pad section 450 may not be covered by interlayer dielectric layer 200. Pad section 450 may allow optical images that have been converted into electric signals to be transmitted to an external circuit.

Color filter layers 300 may be formed over interlayer dielectric layer 200 to correspond with photodiodes 400. Color filter layers 300 include insulating materials that allow light having specific wavelength bands to pass through. Planar layer 250 may be formed over color filter layer 300. In embodiments, planar layer 250 may include organic materials. In embodiments, planer layer 250 may have a thickness of about 0.5 μm to about 1.5 μM. In embodiments, planer layer 250 may have relatively high transparency to visible light. In embodiments, planer layer 250 maybe configured to protect color filter layer 300.

Micro-lens 500 may be formed over planar layer 250. In embodiments, micro-lens 500 may guide light into photodiodes 400. In embodiments, planer layer 250 maybe configured to have micro-lens 500 formed thereon. In embodiments, planar layer 250 may be configured to adjust the focal length of micro-lens 500. Micro-lens 500 may include a photoresist and/or insulating material having relatively high insulating characteristics, while allowing light to pass through. Micro-lens 500 may have a convex surface to facilitate light collection.

FIGS. 3A to 3G are sectional views illustrating methods of manufacturing image sensors, according to embodiments. As illustrated in FIG. 3A, photodiodes 400 and/or pad section 450 may be formed in semiconductor substrate 100. As illustrated in FIG. 3B, protective layer 220 (e.g. including a trench having a predetermined pattern) may be formed over semiconductor substrate 100. Protective layer 220 may include silicon oxide (SiO) based materials, in accordance with embodiments. Trenches may be formed in protective layer 220. Trenches formed in protective layer 220 may have a predetermined pattern. In embodiments, the pitch of a pattern of trenches formed in protective layer 220 may be between about 10 nm and about 3 μM. In embodiments, the depth of trenches formed in protective layer 220 may be the thickness of protective layer 220 or less than the thickness of protective layer 220.

A trench may be formed in protective layer 220 over pad section 450 to expose pad section 450. In embodiments, a trench formed over pad section 450 may extend through the entire thickness of protective layer 220.

As illustrated in FIG. 3C, interlayer dielectric layer 200 may be formed over the protective layer 220, in accordance with embodiments. Interlayer dielectric layer may be formed in trenches formed in protective layer 220 to fill the trenches. In embodiments, interlayer dielectric layer 200 may include silicon nitride (SiN) based materials. As illustrated in FIG. 3D, a predetermine portion of interlayer dielectric layer 200 formed over pad section 450 may be removed, in accordance with embodiments. In embodiments, a predetermined portion of interlayer dielectric layer 200 may be removed so that pad section 450 remains exposed. In embodiments, a portion of interlayer dielectric layer 200 over pad section 450 may be removed after or before a process of forming micro-lens 500.

As illustrated in FIG. 3E, color filter layers 300 may be formed over interlayer dielectric layer 200, in accordance with embodiments. In embodiments, color filter layers 300 may allow light having predetermined wavelength bands to pass through. Color filter layers 300 may be arranged to correspond to the positioning of photodiodes 400.

As illustrated in FIG. 3F, planar layer 250 may be formed over color filter layers 300, in accordance with embodiments. In embodiments, planar layer 250 may include organic materials. In embodiments, planar layer 250 may have a thickness between about 0.5 μm and about 1.5 μM. In embodiments, planar layer 250 may have relatively high transparency to visible light. Planar layer may be configured to effectively protect color filter layer 300.

As illustrated in FIG. 3G, micro-lens 500 may be formed over planar layer 250, in accordance wit embodiments. Planar layer 250 may be configured to adjust the focal length of micro-lens 500. Micro-lens 500 may include a photoresist and/or insulating material having relatively high insulating characteristics, while maintaining transparency. Micro-lens 500 may have a convex surface to facilitate for light collection.

In accordance with embodiments, a trench having a predetermined pattern may be formed over a protective layer aligned below an interlayer dielectric layer. An interlayer dielectric layer may fill a trench in a protective, so that light incident from the exterior is totally reflected from the interfacial surface of the trench, in accordance with embodiments.

If external light is totally reflected from an interfacial surface of a trench in a protective layer without being refracted, the light may be prevented from leaking into an adjacent pixel, which may make it is possible to fabricate an image sensor having superior color reproduction and photo sensitivity, in accordance with embodiments. In embodiments, since a protective layer may engage with a interlayer dielectric layer through a trench, a peeling phenomenon may be prevented.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus comprising:
a semiconductor substrate;
a photo sensor formed in the semiconductor substrate;
a protective layer formed over the semiconductor substrate; and
at least one trench formed in the protective layer over the photo sensor.

2. The apparatus of claim 1, wherein the photo sensor is a photo diode.

3. The apparatus of claim 1, wherein said at least one trench has a predetermined pattern.

4. The apparatus of claim 3, wherein the predetermined pattern is configured to internally reflect light incident on the protective layer over the photo sensor into the photo sensor.

5. The apparatus of claim 3, wherein the predetermined pattern is configured to prevent light incident on the protective layer over the photo sensor from being refracted to an adjacent photo sensor.

6. The apparatus of claim 3, wherein the pitch of the predetermined pattern is between about 10 nm to about 3 μm.

7. The apparatus of claim 1, wherein a dielectric layer is formed over the protective layer, wherein the dielectric layer fills said at least one trench.

8. The apparatus of claim 7, wherein the refractive index of the dielectric layer is greater than the refractive index of the protective layer.

9. The apparatus of claim 7, wherein the dielectric layer is an interlayer dielectric layer.

10. The apparatus of claim 7, wherein:
a color filter is formed over the dielectric layer;
a planar layer is formed over the color filter; and
a micro-lens is formed over the planar layer.

11. A method comprising:
forming a semiconductor substrate;
forming a photo sensor in the semiconductor substrate;
forming a protective layer over the semiconductor substrate; and
forming at least one trench in the protective layer over the photo sensor.

12. The method of claim 11, wherein the photo sensor is a photo diode.

13. The method of claim 11, wherein said at least one trench has a predetermined pattern.

14. The method of claim 13, wherein the predetermined pattern is configured to internally reflect light incident on the protective layer over the photo sensor into the photo sensor.

15. The method of claim 13, wherein the predetermined pattern is configured to prevent light incident on the protective layer over the photo sensor from being refracted to an adjacent photo sensor.

16. The method of claim 13, wherein the pitch of the predetermined pattern is between about 10 nm to about 3 μm.

17. The method of claim 11, comprising forming a dielectric layer over the protective layer, wherein said forming the dielectric layer comprises filling said at least one trench.

18. The method of claim 17, wherein the refractive index of the dielectric layer is greater than the refractive index of the protective layer.

19. The method of claim 17, wherein the dielectric layer is an interlayer dielectric layer.

20. The method of claim 17, comprising:
forming a color filter over the dielectric layer;
forming a planar layer over the color filter; and
forming a micro-lens over the planar layer.
